(19) United States
(12) Patent Application Publication
(10) Pub. No.: US 2021/0382528 A1
(43) Pub. Date: Dec. 9, 2021

(54) LIGHT SOURCE MODULE AND COMPUTING DEVICE USING SAME

(71) Applicant: Primax Electronics Ltd., Taipei (TW)

(72) Inventors: Wei-Ping Chan, Taipei (TW); Wei-Chiang Huang, Taipei (TW)

(21) Appl. No.: 16/939,816

(22) Filed: Jul. 27, 2020

(30) Foreign Application Priority Data
Jun. 5, 2020 (TW) 109119015

(51) Int. Cl. G06F 1/18; F21V 23/06; F21V 33/00; H05K 1/02; H05K 1/03; H01R 13/24

(52) U.S. Cl. CPC G06F 1/182; F21V 23/06; F21V 33/0052; H05K 1/0277; H05K 2201/0326; H05K 1/0306; H01R 13/24; H05K 2201/0145; H05K 1/0353

(57) ABSTRACT

A light source module includes a transparent conductive substrate, a circuit assembly and a light-emitting element. The circuit assembly is electrically connected with a conductive film of the transparent conductive substrate. The circuit assembly includes a feed terminal. The feed terminal is coupled with a po-go pin. The light-emitting element is installed on the conductive film of the transparent conductive substrate. The present invention also provides a computing device with the light source module.

### FIELD OF THE INVENTION

The present invention relates to an optical device, and more particularly to a light source module and a computing device with the light source module.

### BACKGROUND OF THE INVENTION

With the development of electronic industries and the advance of industrial technologies, various electronic products are designed toward small size, slimness, light weightiness and easy portability. Consequently, these electronic products can be applied to mobile business, entertainment or leisure purposes whenever or wherever the users are. Recently, people pay much attention to the integrations and applications of mechanical, optical and electrical technologies. Consequently, a variety of light source modules are gradually and extensively applied to various electronic products. For example, a light source module is applied to a casing of a computer for electronic sports. Consequently, the casing of the computer can provide an awesome luminous effect.

FIG. 1 schematically illustrates the layout structure of a conventional light source module. As shown in FIG. 1, the light source module 1 comprises a transparent conductive substrate 11 and plural light-emitting elements 12. The transparent conductive substrate 11 comprises a substrate base 111 and a conductive film 112. The conductive film 112 is installed on the substrate base 111. For example, the conductive film 112 is made of indium tin oxide (ITO). Moreover, plural conductor lines 1121 are formed on the conductive film 112. The light-emitting elements 12 are installed on the corresponding conductor lines 1121. The conductive film 112 is connected with a power source through additional wires 13. The light-emitting elements 12 acquire the electric power from the power source through the wires 13 and the conductive film 112. Consequently, the light-emitting elements 12 are enabled to emit light beams.

However, the conventional light source module 1 still has some drawbacks. For example, as the number of the light-emitting elements 12 increases, the number of the wires 13 increases. Since the wires 13 are exposed outside, the appearance of the conventional light source module 1 is not aesthetically pleasing and the exposed wires 13 are readily pulled and damaged by the external force. When the light source module 1 is applied to an electronic product, too many wires 13 are detrimental to the efficiency of assembling the light source module 1.

In other words, the conventional light source module and the computing device with the light source module need to be further improved.

### SUMMARY OF THE INVENTION

An object of the present invention provides a light source module with a feed terminal. The feed terminal is coupled with a po-go pin to receive electric power.

Another object of the present invention provides a computing device with the light source module.

In accordance with an aspect of the present invention, a light source module is provided. The light source module includes a transparent conductive substrate, a circuit assembly and a light-emitting element. The transparent conductive substrate includes a substrate base and a conductive film. The conductive film is installed on the substrate base. The conductive film is made of indium tin oxide (ITO). The circuit assembly is installed on the transparent conductive substrate. The circuit assembly includes a feed terminal. The feed terminal is electrically connected with the conductive film and coupled with a po-go pin to acquire an electric power. The light-emitting element is installed on the conductive film. When the light-emitting element receives the electric power, the light-emitting element is enabled to emit a light beam.

In an embodiment, the substrate base is made of glass or polyethylene terephthalate (PET).

In an embodiment, the circuit assembly is a flexible printed circuit assembly (FPCA).

In an embodiment, the transparent conductive substrate further comprises a fastening hole. After a fastening element is penetrated through the fastening hole and tightened in a device with the po-go pin, the transparent conductive substrate and the device are combined together.

In an embodiment, the conductive film includes plural conductor lines, and the plural conductor lines are electrically connected between the po-go pin and the light-emitting element. The electric power is transmitted to the light-emitting element through the po-go pin, the feed terminal and the conductor lines sequentially.

In accordance with another aspect of the present invention, a computing device is provided. The computing device includes a casing and a light source module. The casing includes a po-go pin. The po-go pin is connected with a power source. The light source module is installed on the casing. The light source module includes a transparent conductive substrate, a circuit assembly and a light-emitting element. The transparent conductive substrate includes a substrate base and a conductive film. The conductive film is installed on the substrate base. The conductive film is made of indium tin oxide (ITO). The circuit assembly is installed on the transparent conductive substrate. The circuit assembly includes a feed terminal. The feed terminal is electrically connected with the conductive film. The feed terminal is coupled with the po-go pin to acquire an electric power from the power source when the light source module is installed on the casing. The light-emitting element is installed on the conductive film. When the light-emitting element receives the electric power, the light-emitting element is enabled to emit a light beam.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the layout structure of a conventional light source module;

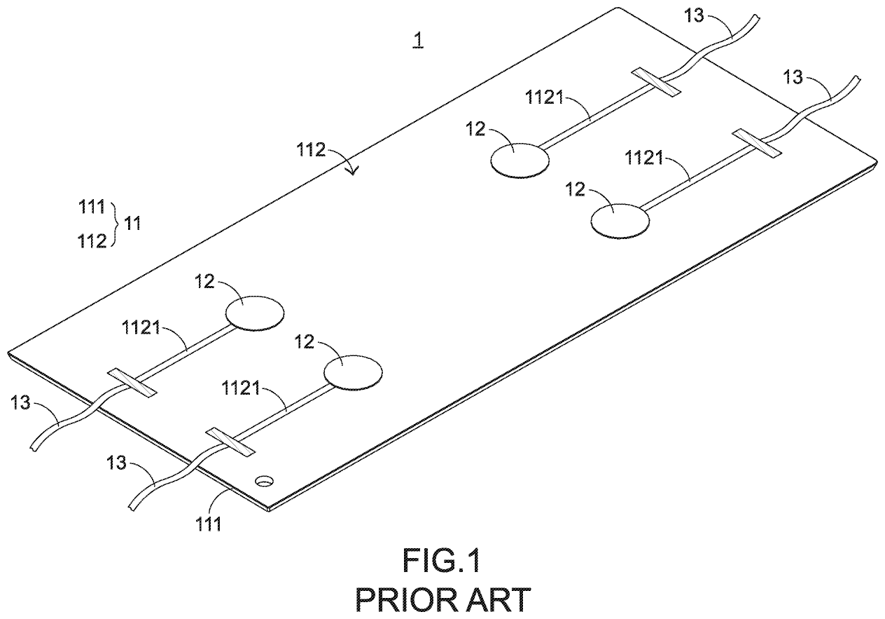

FIG. 2 schematically illustrates the layout structure of a light source module according to an embodiment of the present invention;

FIG. 3 is a schematic perspective view illustrating the appearance of a computing device with the light source module of the present invention; and

FIG. 4 is a schematic exploded view illustrating a portion of the computing device as shown in FIG. 3.

### DETAILED DESCRIPTION OF THE PREFERRED EMBODIMENT

The embodiments of present invention will be described more specifically with reference to the following drawings. Generally, in the drawings and specifications, identical or similar components are designated by identical numeral references. For well understanding the present invention, the elements shown in the drawings are not in scale with the elements of the practical product. In the following embodiments and drawings, the elements irrelevant to the concepts of the present invention or the elements well known to those skilled in the art are omitted. It is noted that numerous modifications and alterations may be made while retaining the teachings of the invention.

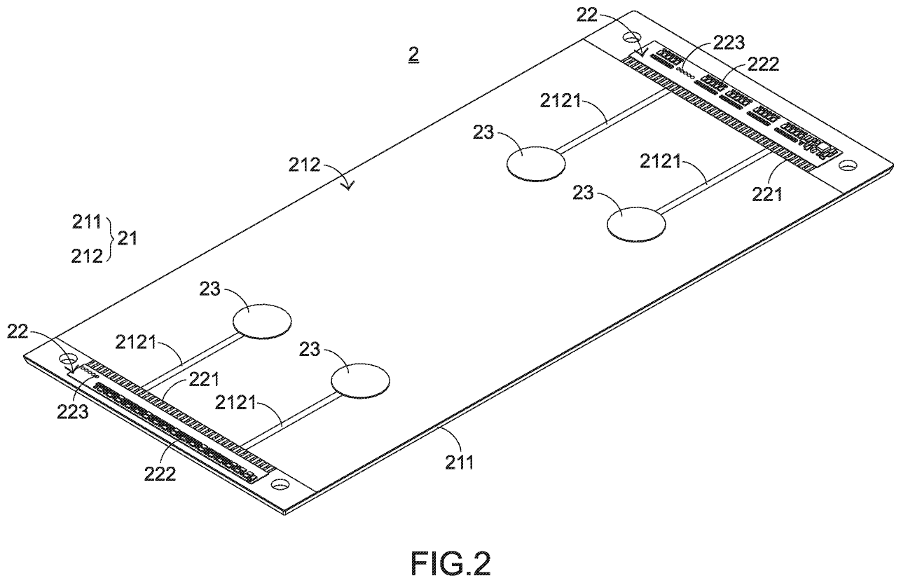

FIG. 2 schematically illustrates the layout structure of a light source module according to an embodiment of the present invention. As shown in FIG. 2, the light source module 2 comprises a transparent conductive substrate 21, a circuit assembly 22 and plural light-emitting elements 23. The transparent conductive substrate 21 comprises a substrate base 211 and a conductive film 212. The conductive film 212 is installed on the substrate base 211. For example, the conductive film 212 is made of indium tin oxide (ITO). Moreover, plural conductor lines 2121 are formed on the conductive film 212. The light-emitting elements 23 are installed on the corresponding conductor lines 2121. The layout and distribution of the conductor lines 2121 are presented herein for purpose of illustration and description only. The method of forming the conductive film 212 on the substrate base 211 is well known to those skilled in the art, and not redundantly described herein. For example, the conductive film 212 is formed through a magnetron sputtering method.

In an embodiment, the substrate base 211 is a glass substrate base or a polyethylene terephthalate (PET) substrate base, and the circuit assembly 22 is a flexible printed circuit assembly (FPCA). The circuit assembly 22 is electrically bonded to the conductor lines 2121 of the conductive film 212 through a connection part 221. It is noted that the types of the substrate base 211 and the circuit assembly 22 are not restricted.

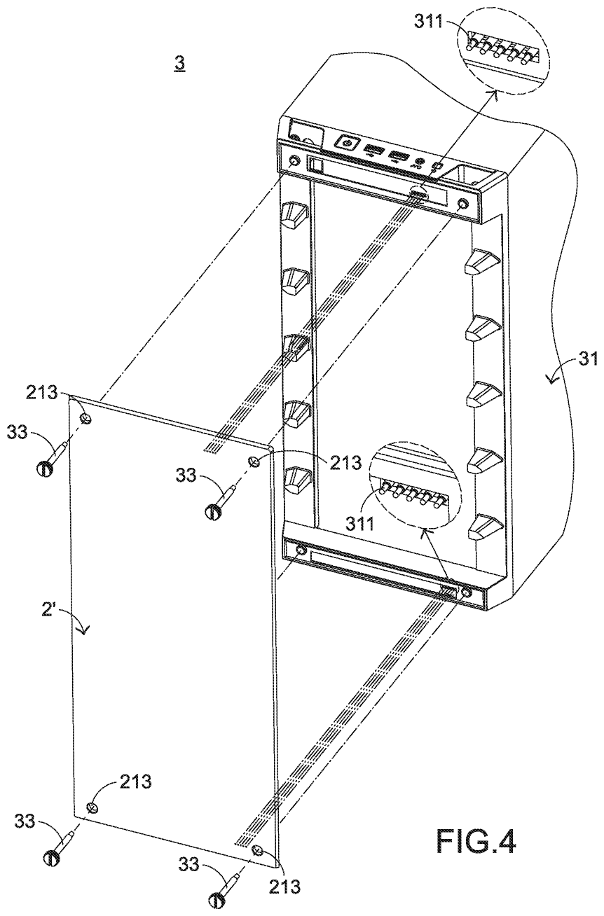

In an embodiment, the circuit assembly 22 further comprises an electronic circuit 222 and plural feed terminals 223. The electronic circuit 222 is used for controlling the operations of the light-emitting elements 23. When the feed terminals 223 are electrically connected with corresponding po-go pins 311 (see FIG. 4) to receive electric power from an external power source, the electric power is transmitted to the light-emitting elements 23 through the po-go pins 311, the feed terminals 223 of the circuit assembly 22 and the conductor lines 2121 of the transparent conductive substrate 21 sequentially. Consequently, the light-emitting elements 23 emit the light beams.

As previously described, the conventional light source module 1 has the problems resulted from the exposed wires. Since the light source module 2 of the present invention does not have the problems of the exposed wires, the appearance of the light source module 2 is aesthetically pleasing and the light source module 2 is not pulled or damaged by the external force.

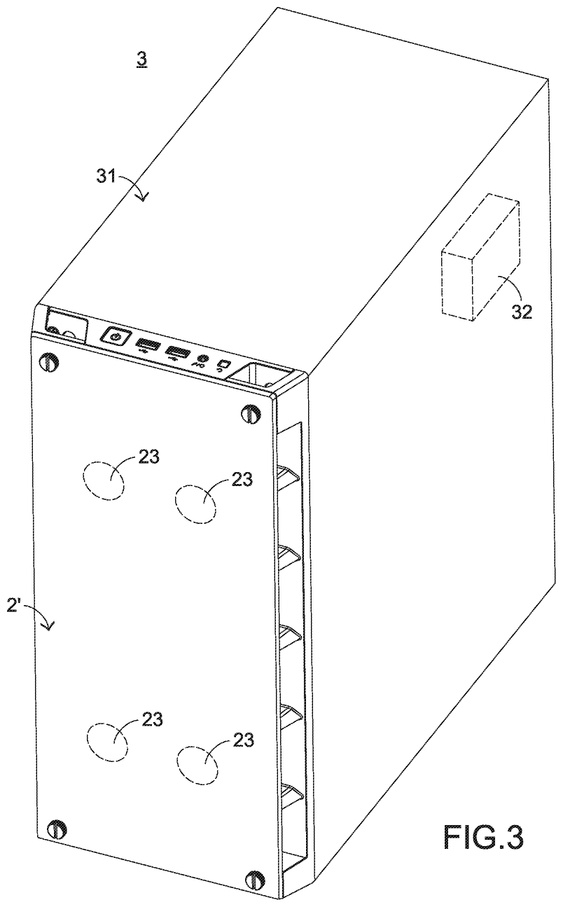

Please refer to FIGS. 3 and 4. FIG. 3 is a schematic perspective view illustrating the appearance of a computing device with the light source module of the present invention. FIG. 4 is a schematic exploded view illustrating a portion of the computing device as shown in FIG. 3. The computing device 3 comprises a casing 31 and a light source module 2′. The po-go pins 311 is installed on the casing 31 and electrically connected with a power source 32. The power source 32 is power supply or a standalone power source for powering the computing device 3.

The structure of the light source module 2′ is similar to that of the light source module as shown in FIG. 2. The light source module 2′ is installed on the casing 31. When the light source module 2′ is installed on the casing 31, the feed terminals 223 of the circuit assembly 22 of the light source module 2′ are coupled with the corresponding po-go pins 311 on the casing 31. Consequently, the po-go pins 311 receive the electric power from the power source 32. The electric power from the power source 32 is transmitted to the light-emitting elements 23 through the po-go pins 311 of the casing 31, the feed terminals 223 of the circuit assembly 22 and the conductor lines 2121 of the transparent conductive substrate 21. Consequently, the light-emitting elements 23 emit the light beams.

Preferably but not exclusively, the transparent conductive substrate 21 of the light source module 2′ further comprises fastening holes 213. After fastening elements 33 (e.g., screws) are penetrated through the corresponding fastening holes 213 and tightened in the casing 31, the transparent conductive substrate 21 is combined with and fixed on the casing 31. In other words, the process of assembling the light source module 2′ is very simple.

It is noted that numerous modifications and alterations may be made while retaining the teachings of the invention. For example, when the light source module is applied to another electronic device, the electronic device has the luminous effect. In case that any appropriate electronic device comprises the po-go pins to be electrically connected with the power source, the light source module of the present invention can be combined with the electronic device through the fastening elements or any other appropriate fastening means. Consequently, the feed terminals are coupled with the corresponding po-go pins to acquire the electric power to power the light-emitting elements.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A light source module, comprising:
a transparent conductive substrate comprising a substrate base and a conductive film, wherein the conductive film is installed on the substrate base, and the conductive film is made of indium tin oxide (ITO);
a circuit assembly installed on the transparent conductive substrate, and comprising a feed terminal, wherein the feed terminal is electrically connected with the conductive film and coupled with a po-go pin to acquire an electric power; and
a light-emitting element installed on the conductive film, wherein when the light-emitting element receives the electric power, the light-emitting element is enabled to emit a light beam.

2. The light source module according to claim 1, wherein the substrate base is made of glass or polyethylene terephthalate (PET).

3. The light source module according to claim 1, wherein the circuit assembly is a flexible printed circuit assembly (FPCA).

4. The light source module according to claim 1, wherein the transparent conductive substrate further comprises a fastening hole, wherein after a fastening element is penetrated through the fastening hole and tightened in a device with the po-go pin, the transparent conductive substrate and the device are combined together.

5. The light source module according to claim 1, wherein the conductive film comprises plural conductor lines, and the plural conductor lines are electrically connected between the po-go pin and the light-emitting element, wherein the electric power is transmitted to the light-emitting element through the po-go pin, the feed terminal and the conductor lines sequentially.

6. A computing device, comprising:
a casing comprising a po-go pin, wherein the po-go pin is connected with a power source; and
a light source module installed on the casing, and comprising:
a transparent conductive substrate comprising a substrate base and a conductive film, wherein the conductive film is installed on the substrate base, and the conductive film is made of indium tin oxide (ITO);
a circuit assembly installed on the transparent conductive substrate, and comprising a feed terminal, wherein the feed terminal is electrically connected with the conductive film, and the feed terminal is coupled with the po-go pin to acquire an electric power from the power source when the light source module is installed on the casing; and
a light-emitting element installed on the conductive film, wherein when the light-emitting element receives the electric power, the light-emitting element is enabled to emit a light beam.

7. The computing device according to claim 6, wherein the substrate base is made of glass or polyethylene terephthalate (PET).

8. The computing device according to claim 6, wherein the circuit assembly is a flexible printed circuit assembly (FPCA).

9. The computing device according to claim 6, wherein the transparent conductive substrate is fixed on the casing through a fastening element.

10. The computing device according to claim 6, wherein the conductive film comprises plural conductor lines, and the plural conductor lines are electrically connected between the po-go pin and the light-emitting element, wherein the electric power from the power source is transmitted to the light-emitting element through the po-go pin, the feed terminal and the conductor lines sequentially.
